(19) United States
(12) Patent Application Publication
(10) Pub. No.: US 2008/0242045 A1
(43) Pub. Date: Oct. 2, 2008

(54) METHOD FOR FABRICATING TRENCH DIELECTRIC LAYER IN SEMICONDUCTOR DEVICE

(75) Inventors: Keum Bum LEE, Icheon-si (KR); Dong Su Park, Icheon-si (KR); Jun Soo Chang, Icheon-si (KR); Eun A Lee, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/951,965

(22) Filed: Dec. 6, 2007

(30) Foreign Application Priority Data
Mar. 27, 2007 (KR) 10-2007-0029871

(51) Int. Cl. H01L 21/62

(52) U.S. Cl. 438/435; 257/E21.52

(57) ABSTRACT

A method for fabricating a trench dielectric layer in a semiconductor device is provided. A trench is formed in a semiconductor substrate and a liner nitride layer is then formed on an inner wall of the trench. A liner oxide layer formed on the liner nitride layer is nitrified in order to protect the liner nitride layer from being exposed. Subsequently, the trench is filled with one or more dielectric layers.

### CROSS-REFERENCES TO RELATED APPLICATIONS

Priority to Korean patent application number 10-2007-0029871, filed on Mar. 27, 2007, the disclosure of which is incorporated by reference in its entirety, is claimed.

### BACKGROUND OF THE INVENTION

The present invention relates to a method for fabricating a semiconductor device and, more particularly, to a method for fabricating a trench dielectric layer in a semiconductor device. As the semiconductor device has become highly integrated, a shallow trench isolation (STI) process having a superior isolation characteristic is mainly used. An dielectric layer is known to exert an influence upon a characteristic of a memory device, such as a DRAM. For example, the dielectric layer exerts an influence upon a data retention time so the STI process has become more significant. Recently, the size of semiconductor devices has been reduced and the line width of a trench has been narrowed. As a result, an aspect ratio of the trench has become greater, and thus a gap fill margin for filling the trench has become more reduced.

A new process of forming an dielectric layer is attempted. For example, the bottom of the trench is filled with a spin on dielectric (SOD) layer having a good fluidity, and then a high density plasma oxide layer is deposited on the resultant structure. An etching process is performed on the SOD layer in order to remove the SOD layer by a predetermined thickness. However, in such an etching process, a liner oxide layer formed on an inner wall of the trench can be partially removed and a liner nitride layer formed on the inner wall of the trench is exposed. The exposed liner nitride layer is locally damaged by plasma generated in the following process of depositing the high density plasma oxide layer. Consequently, a bad influence is exerted upon the characteristic of the device. For example, if the liner nitride layer is damaged, the characteristic of a gate insulating layer may be deteriorated. In addition, impurities included in an active area of a substrate can be diffused into the dielectric layer during the subsequent thermal process. If the impurities are diffused into the dielectric layer, a threshold voltage of a cell is changed or a leakage current is incurred, thereby deteriorating refresh and data retention characteristics of the semiconductor device.

### SUMMARY OF THE INVENTION

Embodiments of the present invention are directed to providing a method for fabricating a trench dielectric layer in a semiconductor device.

In one embodiment, a method for fabricating a trench dielectric layer in a semiconductor device includes forming a trench in a semiconductor substrate, forming a liner nitride layer on an inner wall of the trench, forming a liner oxide layer on the liner nitride layer and nitrifying the liner oxide layer. The method further includes filling the trench with a first dielectric layer, etching the first dielectric layer by a predetermined thickness so as to expose a top of the trench, and filling the trench having the first dielectric layer with a second dielectric layer. The inner wall of the trench is oxidized before forming the liner nitride layer. The liner oxide layer has a thickness of about 80 Å to 100 Å.

A nitrification treatment is performed on the liner oxide layer so that the liner oxide layer has a thickness of about 25 Å to 35 Å. The nitrification treatment includes a plasma process or a heat treatment process. The nitrification treatment is performed for about 50 minutes to 60 minutes under a temperature of about 800° C. to 900° C. The nitrification treatment employs gas including one of NO, N₂O, N₂, and a mixture thereof. The first dielectric layer includes a spin on dielectric layer and the second dielectric layer includes a high density plasma oxide layer.

### BRIEF DESCRIPTION OF THE DRAWINGS

FIGS. 1 to 8 are sectional views illustrating a method for fabricating a trench dielectric layer in a semiconductor device according to the present invention.

### DESCRIPTION OF SPECIFIC EMBODIMENTS

Hereinafter, exemplary embodiments of the present invention will be described with reference to accompanying drawings.

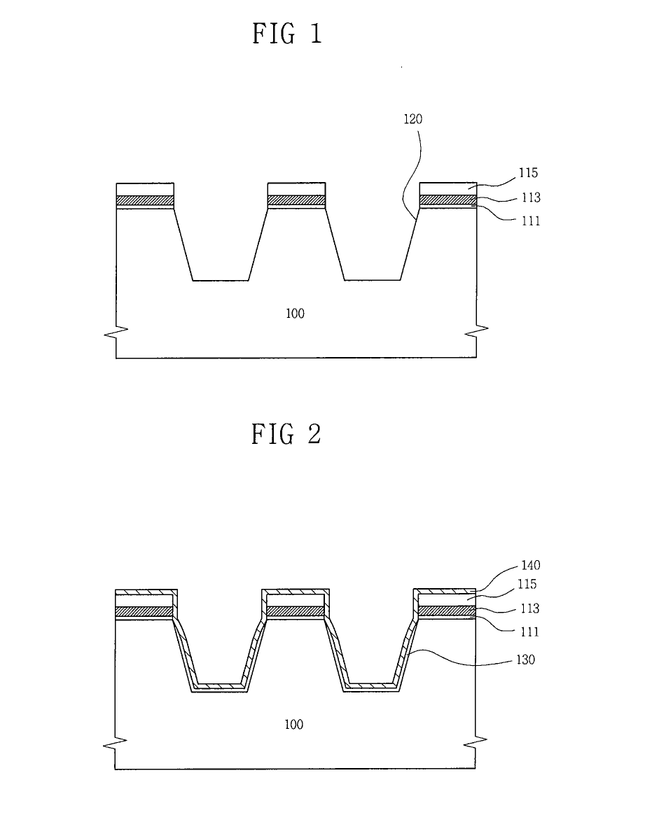

Referring to FIG. 1, a pad oxide layer 111, a pad nitride layer 113 and an oxide layer 115 are formed on a semiconductor substrate 100. The pad nitride layer 113 and the oxide layer 115 can be used as a hard mask during the following etching process to form a trench. A silicon oxide nitride layer (SiON) can be deposited on the oxide layer 115 to form an anti-reflection layer (not shown). The anti-reflection layer is useful for obtaining a uniform line width and process conditions in a photolithography process. However, in some embodiments, the anti-reflection layer may not be included. Next, an etching mask including the oxide layer 115, the pad nitride layer 113 and the pad oxide layer 111 is formed on the semiconductor substrate 100 through the photolithography process to expose an area where an dielectric layer is formed later. The area of the semiconductor substrate 100, which is exposed by the etching mask, is selectively etched to form an isolation trench (trench) 120. The isolation trench 120 may have a depth of about 1500 Å to 1800 Å from a surface of the semiconductor substrate 100.

Referring to FIG. 2, an inner wall oxide layer 130 is formed at an inner wall of the trench 120 (FIG. 1) through an oxidation process. In one embodiment, during the oxidation process, the inner wall of the trench 120 is selectively oxidized such that the inner wall oxide layer 130 has a depth of about 75 Å to 85 Å. As the inner wall oxide layer 130 is formed, a lattice damage of the substrate can be recovered. The lattice damage of the substrate is typically incurred during the etching process for forming the trench 120 (FIG. 1). In addition, the inner wall oxide layer 130 may serve as a buffer layer, which attenuates stress applied to the semiconductor substrate 100 when a liner nitride layer 140 is formed. The liner nitride layer 140 is formed on the semiconductor substrate 100 on which the inner wall oxide layer 130 is formed. The liner nitride layer 140 is formed to a thickness of about 55 Å to 65 Å. The liner nitride layer 140 prevents impurities from being introduced into the dielectric layer during the following heat treatment process, thereby preventing a leakage current.

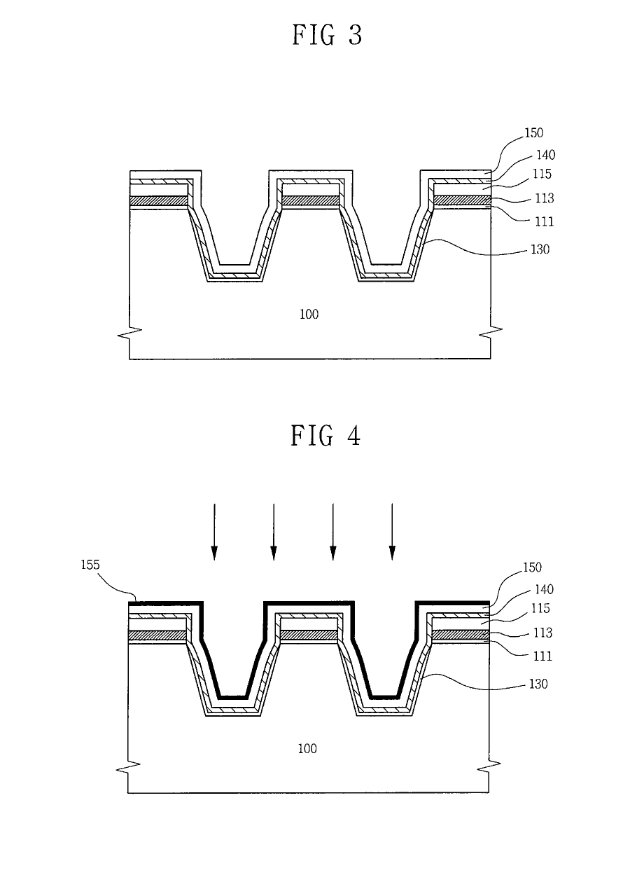

Referring to FIG. 3, a liner oxide layer 150 is formed on the liner nitride layer 140. The liner oxide layer 150 can be formed to have a thickness of about 80 Å to 100 Å.

Referring to FIG. 4, a nitrification treatment is performed on the liner oxide layer 150. In one embodiment, a plasma nitrification treatment is performed to partially nitrify the liner oxide layer 150 so that the liner oxide layer 150 has a thickness of about 25 Å to 35 Å after the plasma nitrification treatment. The nitrification treatment may be performed for about 50 minutes to 60 minutes under a temperature of about 80° C. to 900° C. The plasma nitrification treatment may use nitrogen source gas, for example one of N₂O, NO and N₂, or a mixture thereof, as plasma source gas. The liner oxide layer 150 can be nitrified through any suitable heat treatment process. After the liner oxide layer 150 is nitrified, etching selectivity is increased in a subsequent etching process, thereby minimizing the removal of the liner oxide layer 150. An area 155 is illustrated to show the area of the liner oxide layer 150 that is nitrified.

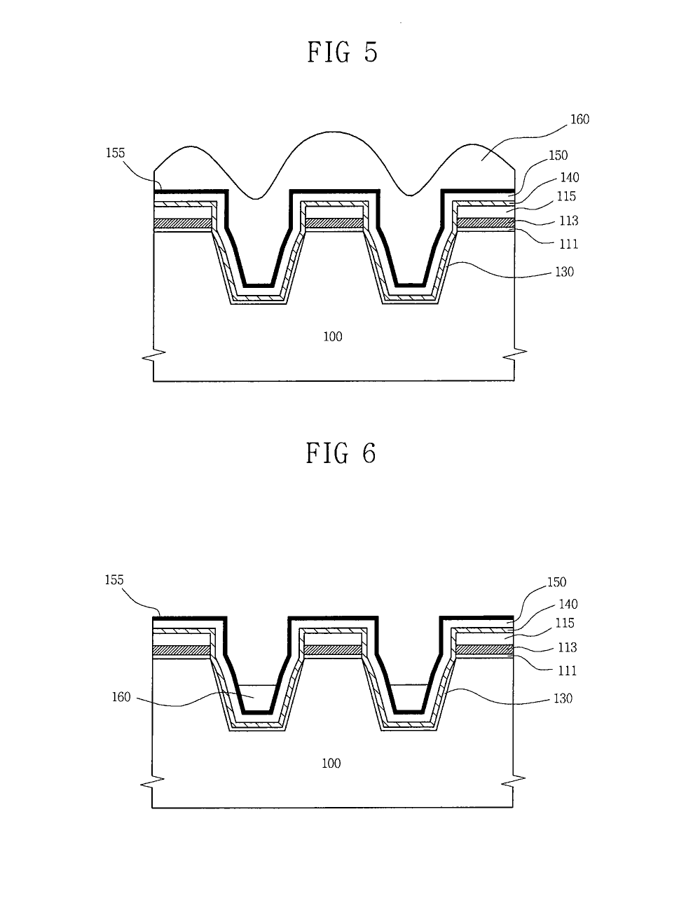

Referring to FIG. 5, a spin on dielectric (SOD) layer 160 is formed on the nitrified liner oxide layer 150, and then the SOD layer 160 is cured through the heat treatment process. As will be well appreciated, the SOD layer 160 has a sparse structure and good fluidity so that the SOD layer 160 can fill the trench 120 (FIG. 1) having a high aspect ratio without causing gap fill defects such as a void.

Referring to FIG. 6, the SOD layer 160 is etched such that the SOD layer 160 having a predetermined thickness remains on a bottom surface of the trench. An etching profile is set to remove the SOD layer 160 by a thickness of about 55 Å to 65 Å from the surface of the semiconductor substrate 100 using a wet solution. Conventionally, the liner oxide layer 150 formed on a sidewall of the trench may be exposed when the SOD layer 160 is removed during the etching process.

However, since the surface of the liner oxide layer 150, which is partially nitrified, has a higher etching selectivity with respect to the SOD layer 160, the loss of the liner oxide layer 150 can be minimized while the SOD layer 160 is being removed. For example, even if the liner oxide layer 150 is lost while the SOD layer 160 is being removed, the liner oxide layer 150 can have a thickness of at least 40 Å to 50 Å. As a result, the liner nitride layer 140 can be prevented from being exposed. As motioned above, the SOD layer 160 remains on the bottom surface of the trench at a predetermined thickness so that the trench can be easily filled with another dielectric layer, for example a high density plasma layer.

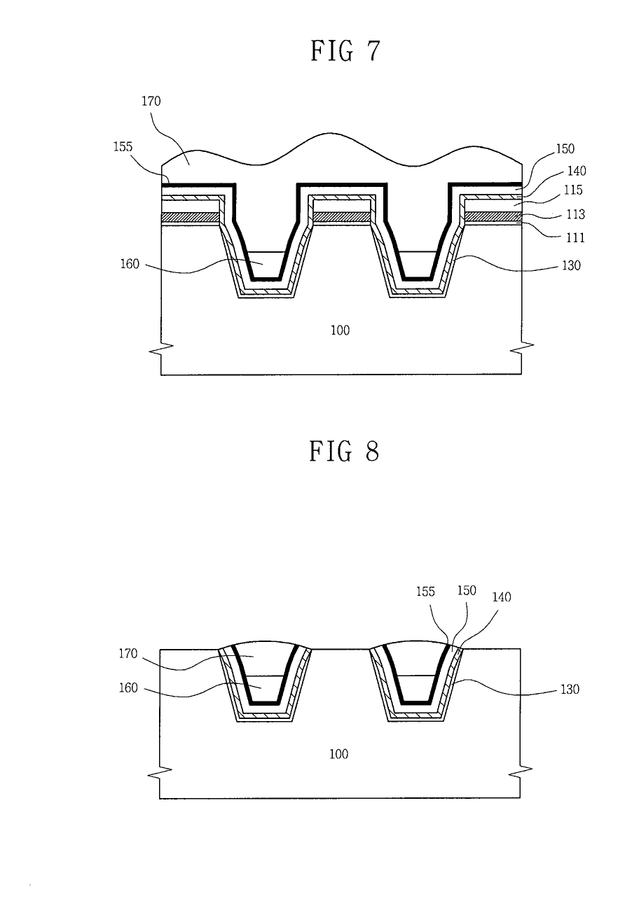

Referring to FIG. 7, a high density plasma oxide layer 170 is formed on the SOD layer 160 which is filled in the trench 120 (FIG. 1). In some embodiments, the semiconductor substrate 100 having the SOD layer 160, is loaded into a plasma chamber, and then deposition source gas is introduced into the plasma chamber to generate the plasma, thereby forming the high density plasma oxide layer 170 on the SOD layer 160 of the semiconductor substrate 100.

Since the SOD layer 160 tends to have a very low density, the SOD layer 160 may be lost during an etching process and cleaning process. In some instances, ions may penetrate into a dielectric layer during an implantation process, which introduces impurities and deteriorates the characteristic of the semiconductor device. In order to prevent such impurities from being introduced into the dielectric layer, the SOD layer 160 is removed by a predetermined thickness such that a portion of the SOD layer 160 remains on the bottom surface of the trench at a predetermined thickness and then an insulating layer having a high density, such as the high density plasma oxide layer 170, is deposited on the remaining SOD layer 160 on the bottom surface of the trench. In this manner, the impurities may be prevented from being introduced into the dielectric layer.

In an aspect of the described embodiments, even when the high density plasma oxide layer 170 is deposited, the liner nitride layer 140 is still protected by the nitrified liner oxide layer 150 from being damaged by the plasma. Therefore, the liner nitride layer 140 is stably protected during the process of forming the dielectric layer, so that the electrical characteristics of the device, such as refresh and charge retention characteristics, can be improved.

Referring to FIG. 8, the high density plasma oxide layer 170 undergoes an etch-back process to form a plurality of insulating layers defining active regions on the semiconductor substrate 100. In one embodiment, the node split can be performed through a chemical mechanical polishing (CMP) process. In that embodiment, a pad nitride layer pattern 113 (FIG. 1) can be used as an etch stop layer during the CMP.

Although preferred embodiments of the present invention have been disclosed for illustrative purposes, those skilled in the art will appreciate that various modifications, additions and substitutions are possible, without departing from the scope and spirit of the invention as defined in the accompanying claims.

What is claimed is:

1. A method for fabricating a trench dielectric layer in a semiconductor device, comprising:
forming a trench in a semiconductor substrate;
forming a liner nitride layer on an inner wall of the trench;
forming a liner oxide layer on the liner nitride layer;
nitrifying the liner oxide layer; and
filling the trench with a dielectric layer.

2. The method of claim 1, further comprising oxidizing the inner wall of the trench to form an inner wall oxide layer before forming the liner nitride layer.

3. The method of claim 1, wherein the liner oxide layer has a thickness of about 80 Å to 100 Å.

4. The method of claim 1, wherein nitrifying the liner oxide layer includes performing a plasma nitrification treatment on the liner oxide layer in order that the liner oxide layer has a thickness of about 25 Å to 35 Å.

5. The method of claim 4, wherein the plasma nitrification treatment is performed for about 50 to 60 minutes at a temperature of about 800° C. to 900° C.

6. The method of claim 4, wherein the plasma nitrification treatment employs gas including NO, N₂O, N₂, or a mixture thereof.

7. The method of claim 1, wherein the forming of the dielectric layer includes:
forming a first dielectric layer on the nitrified liner oxide layer;
etching the first dielectric layer to expose a top of the trench, wherein, after being etched, the first dielectric layer has a predetermined thickness; and
filling the trench by forming a second dielectric layer on the first dielectric layer.

8. The method of claim 7, wherein the first dielectric layer includes a spin on dielectric layer and the second dielectric layer includes a high density plasma oxide layer.

9. A method for fabricating a trench dielectric layer in a semiconductor device, the method comprising:
forming a trench in a semiconductor substrate;
forming a liner nitride layer on an inner wall of the trench;
forming a liner oxide layer on the liner nitride layer;
nitrifying the liner oxide layer;
filling the trench with a first dielectric layer;
etching the first dielectric layer to expose a top of the trench, wherein, after being etching, the first dielectric layer has a predetermined thickness; and
filling the trench by forming a second dielectric layer on the first dielectric layer.

10. The method of claim 9, further comprising oxidizing the inner wall of the trench to form an inner wall oxide layer before forming the liner nitride layer.

11. The method of claim 9, wherein the liner oxide layer has a thickness of about 80 Å to 100 Å.

12. The method of claim 9, wherein nitrifying the liner oxide layer includes performing a nitrification treatment on the liner oxide layer in order that the liner oxide layer has a thickness of about 25 Å to 35 Å.

13. The method of claim 12, wherein the nitrification treatment includes a plasma process or a heat treatment process.

14. The method of claim 12, wherein the nitrification treatment is performed for about 50 minutes to 60 minutes under a temperature of about 800° C. to 900° C.

15. The method of claim 12, wherein the nitrification treatment employs gas including NO, N₂O, N₂ or a mixture thereof.

16. The method of claim 12, wherein the first dielectric layer includes a spin on dielectric layer.

17. The method of claim 12, wherein the second dielectric layer includes a high density plasma oxide layer.
